(19) United States
(12) Patent Application Publication
(10) Pub. No.: US 2022/0192033 A1
(43) Pub. Date: Jun. 16, 2022

(54) CIRCUIT BOARD AND METHOD FOR PRODUCING CIRCUIT BOARD

(71) Applicant: IDEMITSU KOSAN CO.,LTD., Tokyo (JP)

(72) Inventors: Fumioki FUKATSU, Chiba (JP); Satoshi HACHIYA, Chiba (JP)

(73) Assignee: IDEMITSU KOSAN CO.,LTD., Tokyo (JP)

(21) Appl. No.: 17/438,251

(22) PCT Filed: Mar. 10, 2020
(86) PCT No.: PCT/JP2020/010342

§ 371 Date: Sep. 10, 2021

(30) Foreign Application Priority Data
Mar. 12, 2019 (JP) 2019-045128

(51) Int. Cl. H05K 3/38; H05K 1/03; H05K 1/02; C23C 18/20; C23C 18/30; C23C 18/40

(52) U.S. Cl. CPC H05K 3/387; H05K 1/036; H05K 1/0242; C23C 18/204; C23C 18/30; H05K 1/09; H05K 2201/0154; H05K 2201/0141; H05K 2201/015; H05K 2201/0158; C23C 18/40

(57) ABSTRACT

A circuit substrate comprising, in the following stacked order, a resin base material 1 having a dielectric loss tangent of 0.015 or lower, a polyaniline layer 2 comprising a substituted or unsubstituted polyaniline, and a metal layer 3, wherein the metal layer 3 has a surface roughness Rz_{JIS} of 0.5 μm or less at the surface on the side of the polyaniline layer 2.

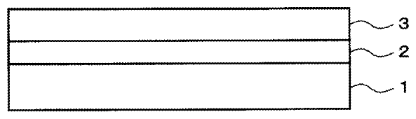

### TECHNICAL FIELD

The invention relates to a circuit substrate and a method of manufacturing a circuit substrate.

### BACKGROUND ART

Recently, the utilization of high-frequency electrical signals has become active in a wide variety of fields including, for example, in-vehicle radar and next-generation mobile phones, etc., and circuit substrates suitable for transmission of high-frequency electrical signals are required.

As a conventional circuit substrate, for example, one in which a base material and a metal layer (copper foil or the like) are bonded together by an adhesive is used as disclosed in Patent Document 1.

### RELATED ART DOCUMENTS

### Patent Documents

[Patent Document 1] JP H5-226831 A

### SUMMARY OF THE INVENTION

When a base material and a metal layer are adhered to each other by an adhesive to form a circuit substrate as in the prior art, a method such as an etching treatment is usually employed, which gives to the surface of the metal layer unevenness (for example, surface roughness Rz_{JIS} of 1 μm or more) and adhesiveness, whereby ensuring anchoring effects. A resin substrate having low dielectric loss tangent is suitable for a circuit substrate for high-frequency electrical signals. However, since a resin substrate having such a low dielectric loss tangent has low adhesiveness with adhesives, the necessity of strengthening the anchor effect by roughening the surface of the metal layer becomes greater.

On the other hand, the higher the frequency of electrical signals is, the more the current concentrates on the surface of the conductor (skin effect), and the transmission distance of high-frequency electrical signals is lengthened in roughened metals, so that greater transmission loss and delay are resulted in. Therefore, in the circuit board for high-frequency electrical signals, it is desired that the metal surface is smooth, but it is difficult to increase the smoothness in view of the adhesiveness.

It is an object of the invention to provide a circuit substrate suitable for transmitting high-frequency electrical signals, and a method of manufacturing the circuit substrate.

As a result of intensive studies by the inventors, it was found that even if the resin substrate has a low dielectric loss tangent, an extremely smooth metal layer can be formed thereon by electroless plating using polyaniline, and the obtained plating laminate (circuit substrate) is excellent in adhesiveness to the metal layer, and the invention was completed.

According to the invention, the following circuit substrate and so on are provided.
1. A circuit substrate comprising, in the following stacked order,

a resin base material having a dielectric loss tangent of 0.015 or lower,

a polyaniline layer comprising a substituted or unsubstituted polyaniline, and

a metal layer,

wherein the metal layer has a surface roughness Rz_{JIS} of 0.5 μm or less at the surface on the side of the polyaniline layer.
2. The circuit substrate according to 1, wherein Rz_{JIS} of 0.25 μm or less at the surface on the side of the polyaniline layer.
3. The circuit substrate according to 1 or 2, wherein the polyaniline layer has a thickness of 5 μm or less.
4. The circuit substrate according to any one of 1 to 3, wherein the resin base material comprises one or more selected from the group consisting of syndiotactic polystyrene, polyimide, liquid crystal polymer, polytetrafluoroethylene, and polyolefin.
5. The circuit substrate according to any one of 1 to 4, wherein the resin base material comprises syndiotactic polystyrene.
6. The circuit substrate according to any one of 1 to 5, wherein the metal layer comprises one or more metals selected from the group consisting of Cu, Ni, Au, Pd, Ag, Sn, Co, and Pt.
7. The circuit substrate according to any one of 1 to 6, wherein the metal layer comprises Cu.
8. The circuit substrate according to any one of 1 to 7, wherein the polyaniline layer comprises a polyaniline complex doped by a dopant as the substituted or unsubstituted polyaniline.
9. The circuit substrate according to 8, wherein the dopant is an organic acid ion derived from a sulfosuccinic acid derivative represented by the following formula (III):

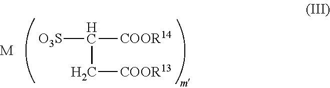

wherein in the formula (III), M is a hydrogen atom, an organic free radical, or an inorganic free radical; m′ is the valence of M; R¹³ and R¹⁴ are independently a hydrocarbon group, or —(R¹⁵O)ᵣ—R¹⁶ group; R¹⁵'s are independently a hydrocarbon group or a silylene group; R¹⁶ is a hydrogen atom, a hydrocarbon group, or a R¹⁷₃Si—group; r is an integer of 1 or more; and R¹⁷'s are independently a hydrocarbon group.
10. The circuit substrate according to 8 or 9, wherein the dopant is sodium di-2-ethylhexyl sulfosuccinate.
11. The circuit substrate according to any one of 1 to 10, which is used in applications for transmitting a high-frequency electrical signal having a frequency of 1 GHz or more.
12. A process for manufacturing a circuit substrate according to any one of 1 to 11, wherein the process for manufacturing a circuit substrate comprises

a step of subjecting a surface of the resin base material to one or more treatments selected from the group consisting of an active energy ray irradiation treatment, a corona treatment, and a frame treatment;

a step of forming a polyaniline layer on the surface of the resin base material undergone the treatment;

a step of having an electroless plating catalyst supported on the polyaniline layer; and

a step of applying electroless plating on the polyaniline layer on which the electroless plating catalyst is supported, to form a metal layer.
13. The process for manufacturing a circuit substrate according to 12, wherein the surface of the resin base material is subjected to an active energy ray irradiation treatment.
14. The process for manufacturing a circuit substrate according to 13, wherein the active energy ray is ultraviolet ray.
15. The process for manufacturing a circuit substrate according to 14, wherein a light source of the ultraviolet ray is a high-pressure mercury lamp or a metal halide lamp.
16. The process for manufacturing a circuit substrate according to any one of 12 to 15, wherein the polyaniline layer is formed by coating method using a composition comprising a substituted or unsubstituted polyaniline.
17. The process for manufacturing a circuit substrate according to 16, wherein the composition comprises a polyaniline complex doped by a dopant as the substituted or unsubstituted polyaniline.
18. The process for manufacturing a circuit substrate according to 17, wherein the composition comprises the polyaniline complex of a concentration of 15% by mass or less.
19. The process for manufacturing a circuit substrate according to any one of 12 to 18, wherein the electroless plating catalyst is Pd.

According to the invention, it is possible to provide a circuit substrate suitable for transmission of high-frequency electrical signals, and a method of manufacturing the circuit substrate.

### BRIEF DESCRIPTION OF THE DRAWINGS

FIGURE is a schematic diagram showing a layer configuration of a circuit substrate according to one embodiment of the invention.

### MODE FOR CARRYING OUT THE INVENTION

Hereinafter, a circuit substrate and so on according to one embodiment of the invention will be described.

In this specification, “x to y” represents a numerical range of “x or more and y or less.”

In addition, when the term “(X) component” is used, for example, even when a commercially available reagent is used, it is intended to refer only to the compound which corresponds to the component (X) in the reagent, and does not include other components (solvents, etc.) in the reagent.

Further, the preferred provisions can be arbitrarily adopted. That is, one preferred provision may be employed in combination with one or more other preferred provisions. Combinations of the preferred ones are more preferable.

### [Circuit Substrate]

FIGURE is a schematic diagram showing a layer configuration of a circuit substrate according to one embodiment of the invention.

The circuit substrate according to one embodiment of the invention comprises, in the following stacked order, a resin base material 1 having a dielectric loss tangent of 0.015 or lower, a polyaniline layer 2 comprising a substituted or unsubstituted polyaniline, and a metal layer 3, wherein the metal layer 3 has a surface roughness Rz_{JIS} of 0.5 μm or less at the surface on the side of the polyaniline layer 2.

Hereinafter, each layer constituting a circuit substrate according to one embodiment of the invention will be described.

### [Resin Base Material]

In one embodiment, the resin base material has a dielectric loss tangent of 0.015 or lower.

The resin used for the resin base material is not particularly limited, and may contain one or more kinds selected from the group consisting of, for example, syndiotactic polystyrene, liquid crystal polymer, polytetrafluoroethylene, polyolefin (e.g., it includes polyethylene, polypropylene, and modified polyolefins), polyphenylene sulfide, polyamide, and the like.

In one embodiment, the dielectric loss tangent of the resin base material is desirably lower, and is 0.015 or lower, preferably 0.01 or lower, and more preferably 0.005 or lower. When the dielectric loss tangent of the resin base material is high, the attenuation in high-frequency circuits tends to increase.

The dielectric loss tangent is measured by the cavity resonator method (JIS R16412007) at a measuring frequency of 10 GHz and a temperature of 25° C. using a measuring device (Network Analyzer “E8361A” manufactured by Keysight Technologies).

### [Polyaniline Layer]

### (Polyaniline)

In one embodiment, the polyaniline layer contains a substituted or unsubstituted polyaniline.

The substituted or unsubstituted polyaniline may be used alone (that means the state in which a “polyaniline complex” described later is not formed), but it is preferable that the polyaniline layer contains a polyaniline complex doped with a dopant as the substituted or unsubstituted polyaniline.

The weight-average molecular weight (hereinafter, referred to as molecular weight) of the polyaniline is preferably 20,000 or more. The molecular weight is preferably 20,000 to 500,000, more preferably 20,000 to 300,000, and even more preferably 20,000 to 200,000. The weight-average molecular weight means the molecular weight of the polyaniline, not that of the polyaniline complex.

The molecular weight distribution is preferably 1.5 or more and 10.0 or less. From the viewpoint of conductivity, a narrower molecular weight distribution is preferable, but from the viewpoint of solubility in a solvent, a wider molecular weight distribution may be preferable.

The molecular weight and the molecular weight distribution are measured in polystyrene equivalent by gel permeation chromatography (GPC).

Examples of the substituent of the substituted polyaniline include straight-chain or branched hydrocarbon groups such as a methyl group, an ethyl group, a hexyl group, and an octyl group; alkoxy groups such as a methoxy group or an ethoxy group; aryloxy groups such as a phenoxy group; halogenated hydrocarbon groups such as an trifluoromethyl group (—CF₃ group).

The polyaniline is preferably unsubstituted polyaniline from the viewpoint of versatility and economical efficiency.

The substituted or unsubstituted polyaniline is preferably are obtained by polymerization in the presence of an acid containing no chlorine atom. The acid containing no chlorine atom includes acids consisting of atoms belonging, for example, to Groups 1 to 16 and 18. Specific examples include phosphoric acid. Examples of the polyaniline obtained by polymerization in the presence of the acid containing no chlorine atom include one obtained by polymerization in the presence of phosphoric acid.

The use of polyaniline produced in the presence of the acid containing no chlorine atom can make the chlorine content of the polyaniline complex to be lower.

Examples of the dopant of the polyaniline complex include, for example, Bronsted acid ions arising from Bronsted acids or salts of Bronsted acid, preferably organic acid ions arising from organic acids or salts of organic acids, and more preferably organic acid ions arising from the compound represented by the following formula (I) (proton donor).

In the invention, when the dopant is expressed as a specific acid and when the dopant is expressed as a specific salt, in each case, the specific acid ion arising from a specific acid or the specific salt is doped into the above-mentioned π-conjugate polymer.

M(XARₙ)ₘ (I)

M in the formula (I) is a hydrogen atom, an organic free radical, or an inorganic free radical.

Examples of the organic free radical include a pyridinium group, an imidazolium group, and an anilinium group, and the like. Examples of the inorganic free radical include ions of lithium, sodium, potassium, cesium, ammonium, calcium, magnesium, iron, and the like.

X in the formula (I) is an anionic group, for example, —SO₃⁻ group, —PO₃²⁻ group, —PO₂(OH)⁻ group, —OPO₃²⁻ group, —OPO₂(OH)⁻ group, —COO— group, and the like, and is preferably —SO₃⁻ group.

A in the formula (I) is a substituted or unsubstituted hydrocarbon group (including, for example, 1 to 20 carbon atoms).

The hydrocarbon group is a open-chain or cyclic saturated aliphatic hydrocarbon group, an open-chain or cyclic unsaturated aliphatic hydrocarbon group, or an aromatic hydrocarbon group.

Examples of the open-chain saturated aliphatic hydrocarbon group include a straight-chain or branched alkyl group (including, for example, 1 to 20 carbon atoms). Examples of the cyclic saturated aliphatic hydrocarbon group include cycloalkyl groups (including, for example, 3 to 20 carbon atoms) such as a cyclopentyl group, a cyclohexyl group, a cycloheptyl group, a cyclooctyl group, and the like. The cyclic saturated aliphatic hydrocarbon group may be a fusion of a plurality of cyclic saturated aliphatic hydrocarbon groups. Examples thereof include a norbornyl group, an adamantyl group, and a fused adamantyl group. Examples of the open-chain unsaturated aliphatic hydrocarbon group (including, for example, 2 to 20 carbon atoms) include a straight-chain or branched alkenyl group. Examples of the cyclic unsaturation aliphatic hydrocarbon group (including, for example, 3 to 20 carbon atoms) include a cyclic alkenyl group. Examples of the aromatic hydrocarbon group (including, for example, 6 to 20 carbon atoms) include a phenyl group, a naphthyl group, and an anthracenyl group.

When A is a substituted hydrocarbon group, the substituent is an alkyl group (including, for example, 1 to 20 carbon atoms), a cycloalkyl group (including, for example, 3 to 20 carbon atoms), a vinyl group, an allyl group, an aryl group (including, for example, 6 to 20 carbon atoms), an alkoxy group (including, for example, 1 to 20 carbon atoms), a halogen atom, a hydroxy group, an amino group, an imino group, a nitro group, a silyl group, or a group containing ester bond.

R in the formula (I) is bonded to A and is —H, or a substituent represented by —R¹, —OR¹, —COR¹, —COOR¹, —(C═O)—(COR¹ or —(C═O)—(COOR¹), and R¹ is a hydrocarbon group which may have a substituent, a silyl group, a alkylsilyl group, a —(R²O)ₓ—R³ group, or a —(OSiR³₂)ₓ—OR³ group. R² is an alkylene group, R³ is a hydrocarbon group, and x is an integer of 1 or more. When x is 2 or more, the plurality of R²'s may be the same as or different from each other, and each of the plurality of R³'s may be the same as or different from each other.

Examples of the hydrocarbon group (including, for example, 1 to 20 carbon atoms) for R¹ include a methyl group, an ethyl group, a butyl group, a pentyl group, a hexyl group, a heptyl group, an octyl group, a nonyl group, a decyl group, a dodecyl group, a pentadecyl group, an eicosanil group, and the like. The hydrocarbon group may be straight-chain or may be branched.

The substituent of the hydrocarbon group is an alkyl group (including, for example, 1 to 20 carbon atoms), a cycloalkyl group (including, for example, 3 to 20 carbon atoms), a vinyl group, an allyl group, an aryl group (including, for example, 6 to 20 carbon atoms), an alkoxy group (including, for example, 1 to 20 carbon atoms), a halogen atom, a hydroxy group, an amino group, an imino group, a nitro group, or a group containing ester bond. Examples of the hydrocarbon group for R³ is the same as those for R¹.

Examples of the alkylene group (including, for example, 1 to 20 carbon atoms) for R² include, for example, a methylene group, an ethylene group, a propylene group, and the like.

n in the formula (I) is an integer of 1 or more. When n is 2 or more, the plurality of R's may be the same as or different from each other.

m in the formula (I) is the valence of M/the valence of X.

As the compound represented by the formula (I), dialkylbenzenesulfonic acid, dialkylnaphthalenesulfonic acid, or a compound containing two or more ester bonds are preferred.

As the compound containing two or more ester bonds is more preferably sulfophthalic ester or a compound represented by the following formula (II):

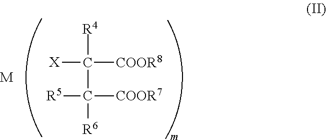

In the formula (II), M and X are the same as those in the formula (I). X is preferably a —SO₃ group. R⁴, R⁵, and R⁶ are independently a hydrogen atom, a hydrocarbon group, or a R⁹₃Si— group. Three R⁹'s are independently a hydrocarbon group.

Examples of the hydrocarbon group for R⁴, R⁵, and R⁶, which are hydrocarbon groups include a straight-chain or branched alkyl group including 1 to 24 carbon atoms, an aryl group containing an aromatic ring (including, for example, 6 to 20 carbon atoms), an alkylaryl group (including, for example, 7 to 20 carbon atoms), and the like.

Examples of the hydrocarbon group for R⁹ are the same as those for R⁴, R⁵, and R⁶.

R⁷ and R⁸ in the formula (II) are independently a hydrocarbon group or a —(R¹⁰O)_{q}—R¹¹ group. R¹⁹ is a hydrocarbon group or a silylene group, R¹¹ is a hydrogen atom, a hydrocarbon group, or R¹²₃Si—, and q is an integer of 1 or more. Three R¹²'s are independently a hydrocarbon group.

Examples of the hydrocarbon group for R⁷ and R⁸, which are hydrocarbon groups include a straight-chain or branched alkyl group including 1 to 24, preferably 4 or more, carbon atoms, an aryl group containing a aromatic ring (including, for example, 6 to 20 carbon atoms), an alkylaryl group (including, for example, 7 to 20 carbon atoms), and the like, and specific examples thereof include, for example, a butyl group, a pentyl group, a hexyl group, an octyl group, a decyl group, and the like, all of which are straight-chain or branched.

Examples of the hydrocarbon group for R¹⁹ in R⁷ and R⁸, which are hydrocarbon groups include, for example, a straight-chain or branched alkylene group including 1 to 24 carbon atoms, an arylene group containing an aromatic ring (including, for example, 6 to 20 carbon atoms), an alkylarylene group (including, for example, 7 to 20 carbon atoms), or an arylalkylene group (including, for example, 7 to 20 carbon atoms). Examples of the hydrocarbon group for R¹¹ and R¹² in R⁷ and R⁸, which are hydrocarbon groups are the same as those for R⁴, R⁵, and R⁶, and q is preferably 1 to 10.

Specific examples of the compound represented by the formula (II) when R⁷ and R⁸ are —R¹⁰O)_{q}—R¹¹ groups include two compounds represented by the following formulas.

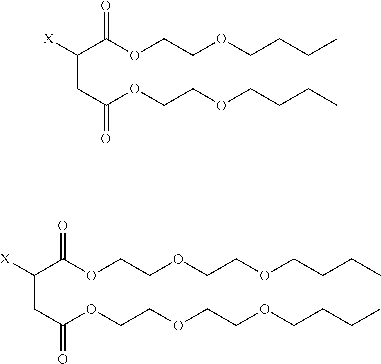

In the formulas, X is the same as that in the formula (I).

It is further preferred that the compound represented by the formula (II) is a sulfosuccinic acid derivative represented by the following formula (III).

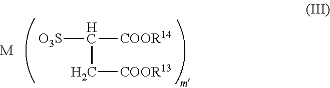

In the formula (III), M is the same as in the formula (I). m′ is the valence of M.

R¹³ and R¹⁴ are independently a hydrocarbon group or a —(R¹⁵O)ᵣ—R¹⁶ group. R¹⁵ is a hydrocarbon group or a silylene group, R¹⁶ is a hydrogen atom, a hydrocarbon group, or a R¹⁷₃Si— group, and r is an integer of 1 or more. Three R¹⁷'s are independently a hydrocarbon group. When r is 2 or more, the plurality of R¹⁵'s may be the same as or different from each other.

The hydrocarbon group for R¹³ and R¹⁴, which are hydrocarbon groups are the same as those for R⁷ and R⁸.

In R¹³ and R¹⁴, the hydrocarbon group for R¹⁵, which is a hydrocarbon group is the same as that for R¹⁰. In R¹³ and R¹⁴, the hydrocarbon group for R¹⁶ and R¹⁷, which are hydrocarbon groups is the same as those for R⁴, R⁵, and R⁶.

r is preferably 1 to 10.

Specific examples of the group for R¹³ and R¹⁴, which are —(R¹⁵O)ᵣ—R¹⁶ groups are the same as —(R¹⁰O)_{q}—R¹¹) for R⁷ and R⁸.

The hydrocarbon group for R¹³ and R¹⁴ is the same as those for R⁷ and R⁸, and is preferably a butyl group, a hexyl group, a 2-ethylhexyl group, and decyl group.

As the compound represented by the formula (I), di-2-ethylhexylsulfosuccinic acid and sodium di-2-ethylhexylsuffosuccinate (Aerosol OT) are preferred.

A dopant being doped into the substituted or unsubstituted polyaniline in the polyaniline complex can be confirmed by ultraviolet/visible/near-infrared spectroscopy or X-ray photoelectron spectroscopy, and the dopant can be used without any particular chemical structural limitation as long as the dopant has enough acidity to generate carriers in the polyaniline.

The doping ratio of the dopant to the polyaniline is preferably 0.35 or more and 0.65 or less, more preferably 0.42 or more and 0.60 or less, still more preferably 0.43 or more and 0.57 or less, and particularly preferably 0.44 or more and 0.55 or less.

The doping ratio is defined as (number of moles of the dopant doped into polyaniline)/(number of moles of monomer unit of polyaniline). For example, a doping ratio of 0.5 for a polyaniline complex containing unsubstituted polyaniline and a dopant means that one dopant is doped with respect to two monomer unit molecules of polyaniline.

The doping ratio can be calculated if the number of moles of the dopant and the monomer unit of the polyaniline in the polyaniline complex can be calculated. For example, when the dopant is an organic sulfonic acid, the number of moles of the sulfur atom derived from the dopant and the number of moles of the nitrogen atom derived from the monomer unit of polyaniline are quantified by an organic elemental analysis method, and from the ratio of these values, the doping ratio can be calculated. However, the method of calculating is not limited to this means.

The polyaniline complex may further contain phosphorus or may not contain phosphorus.

When the polyaniline complex contains phosphorus, the content of phosphorus is, for example, 10 ppm by mass or more and 5000 ppm by mass or less.

The content of phosphorus can be measured by ICP emission spectrometry.

Further, it is preferable that the polyaniline complex does not contain a Group 12 element (e.g., zinc) as an impurity.

The polyaniline complex can be produced in a well-known production method. For example, the polyaniline complex can be produced by chemical oxidative polymerization of a substituted or unsubstituted aniline in a two-liquid phase solution containing a proton donor, phosphoric acid, and an emulsifier different from the proton donor. The polyaniline complex can also be produced by adding an oxidative polymerization agent to a two-liquid phase solution containing a substituted or unsubstituted aniline, a proton donor, phosphoric acid, and an emulsifier different from the proton donor.

Here, “a two-liquid phase solution having two liquid phases” means a state in which two liquid phases incompatible with each other are present in the solution. For example, it means a state in which “a phase of a high polarity solvent” and “a phase of a low polarity solvent” are present in the solution.

In addition, “a two-liquid phase solution having two liquid phases” also includes a state in which one liquid phase is a continuous phase and the other liquid phase is a dispersed phase. Examples thereof include a state in which “a phase of a high polarity solvent” is a continuous phase and “a phase of a low polarity solvent” is a dispersed phase, and a state in which “a phase of a low polarity solvent” is a continuous phase and “a phase of a high polarity solvent” is a dispersed phase.

As such a highly polar solvent used in the above method of producing a polyaniline complex, water is preferred, and as such a low polarity solvent, for example, an aromatic hydrocarbon such as toluene or xylene are preferred.

The proton donor is preferably a compound represented by the formula (I).

As the emulsifier, both ionic emulsifiers, in which the hydrophilic moiety is ionic, and nonionic emulsifiers, in which the hydrophilic moiety is nonionic, may be used, and one emulsifier may be used alone or two or more emulsifiers may be used in combination.

As an oxidizing agent used for chemical oxidative polymerization, peroxides, such as sodium persulfate, potassium persulfate, ammonium persulfate, and hydrogen peroxide; ammonium dichromate, ammonium perchlorate, potassium iron (III) sulfate, iron (III) trichloride, manganese dioxide, iodic acid, potassium permanganate, or iron paratoluenesulfonate, and the like can be used, and persulfates such as ammonium persulfate are preferable.

These may be used alone or in combination of two or more thereof.

### (Binder)

The polyaniline layer may contain a binder in addition to one or more selected from a substituted or unsubstituted polyaniline and a polyaniline complex.

As the binder, the polyaniline layer may contain, for example, one or more selected from the group consisting of acrylics, urethanes, epoxies, polyamides, vinyls, polyvinyl acetals, polyesters, polyester polyols, polyether polyols, and polycarbonates. In addition, a polymer having an acidic group such as a carboxy group or a sulfoxy group in the structure (e.g., an urethane having a carboxy group or a polyester having a carboxy group) is preferred.

The polyaniline layer may further contain a binder obtained by curing a monomer, an oligomer, or a polymer having a reactive functional group such as acrylate or methacrylate at the terminal with ultraviolet ray, electron beam, or the like.

### (Other Component)

The polyaniline layer may contain a component other than the polyaniline and the polyaniline complex, and the binder within a range not impairing the effect of the invention. Examples of such a component include additives such as an inorganic material, a curing agent, a plasticizer, and an organic conductive material.

The inorganic material is added, for example, for the purpose of improving mechanical properties such as strength, surface hardness, dimensional stability, or the like, or increasing electrical properties such as conductivity. Specific examples of the inorganic material include, for example, silica (silicon dioxide), titania (titanium dioxide), alumina (aluminum oxide), Sn-containing In₂O₃ (ITO), Zn-containing In₂O₃, a co-substituted compound of In₂O₃ (an oxide in which tetravalent element and divalent element are substituted with trivalent In), Sb-containing SnO₂ (ATO), ZnO, Al-containing ZnO (AZO), Ga-containing ZnO (GZO), and the like.

The curing agent is added, for example, for the purpose of improving mechanical properties such as strength, surface hardness, dimensional stability, or the like. Specific examples of the curing agent include, for example, a thermosetting agent such as a phenol resin, and a photocuring agent based on an acrylate-based monomer and a photopolymerizable initiator.

The plasticizer is added, for example, for the purpose of increasing mechanical properties such as tensile strength and bending strength. Specific examples of the plasticizer include, for example, phthalic esters and phosphoric esters.

Examples of the organic conductive material include carbon materials such as carbon black, carbon nanotubes, and the like.

The film thickness of the polyaniline layer is not particularly limited. In one embodiment, the film thickness of the polyaniline layer may be, for example, 0.1 μm or more, 0.5 μm or more, or 1 μm or more. The thickness of the polyaniline layer may be, for example, 3 μm or less, 2 μm or less, 1 μm or less, or 0.5 μm or less.

By forming the polyaniline layer thinly, the thickness of the circuit substrate can be reduced. This makes the circuit substrate more compact and easier to install in the mechanical devices. In addition, by forming the polyaniline layer thinly, the surface of the polyaniline layer can be smoothed, whereby the surface roughness Rz_{JIS} of the surface of the metal layer facing the polyaniline layer can be suitably reduced to 0.5 μm or less.

In one embodiment, for example, 70% by mass or more, 80% by mass or more, 90% by mass or more, 98% by mass or more, 99% by mass or more, 99.5% by mass or more, 99.9% by mass or more, or 100% by mass of the polyaniline layer may be composed of:

one or more selected from a substituted or unsubstituted polyaniline and a polyaniline complex, one or more selected from a substituted or unsubstituted polyaniline and a polyaniline complex, and a binder, or one or more selected from a substituted or unsubstituted polyaniline and a polyaniline complex, a binder, and one or more components arbitrary selected from the other components described above.

The resin composition according to an aspect of the invention may be consisting essentially of

one or more selected from a substituted or unsubstituted polyaniline and a polyaniline complex,

one or more selected from a substituted or unsubstituted polyaniline and a polyaniline complex, and a binder, or

one or more selected from a substituted or unsubstituted polyaniline and a polyaniline complex, a binder, and one or more components arbitrary selected from the other components described above.

In this case, an unavoidable impurity may be contained.

In one embodiment, the content of the substituted or unsubstituted polyaniline in the polyaniline layer may be 5% by mass or more, 10% by mass or more, 15% by mass or more, 20% by mass or more, or 25% by mass or more. When the content of the substituted or unsubstituted polyaniline in the polyaniline layer is 5% by mass or more, good electroless plating deposition is resulted in. The upper limit is not particularly limited, and may be, for example, 100% by mass or less, 90% by mass or less, 80% by mass, 70% by mass or less, or 65% by mass or less. When the content of the substituted or unsubstituted polyaniline in the polyaniline layer is less than 100% by mass, for example, when the content is small such as 90% by mass or less, 80% by mass, 70% by mass or less, or even 65% by mass or less, the adhesion and the coating film strength of the polyaniline layer can be increased by addition of a binder or the like. The content of the substituted or unsubstituted polyaniline herein is the total content of the substituted or unsubstituted polyaniline forming the polyaniline complex and the substituted or unsubstituted polyaniline not forming the polyaniline complex.

### [Metal Layer]

The metal layer is a layer containing a metal.

The metal is not particularly limited, and the metal layer may include, for example, one or more metals selected from the group consisting of Cu, Ni, Au, Pd, Ag, Sn, Co, and Pt. In one embodiment, the metal layer contains Cu.

The metal layer may be a single layer or a plating laminate of two or more layers having different metal compositions.

In one embodiment, the surface roughness Rz_{JIS} of the surface of the metal layer facing the polyaniline layer may be 0.5 μm or less, 0.45 μm or less, 0.40 μm or less, 0.35 μm or less, 0.3 μm or less, 0.25 μm or less, 0.2 μm or less, 0.15 μm or less, 0.1 μm or less, 0.08 μm or less, 0.05 μm or less, or 0.02 μm or less. Since the surface roughness Rz_{JIS} is small, transmission loss of high-frequency electrical signals can be more suppressed. The lower limit of the surface roughness Rz_{JIS} is not particularly limited, and may be, for example, 0.005 μm or more, 0.007 μm or more, or 0.01 μm or more.

The surface roughness Rz_{JIS} is a ten-point mean roughness measured in accordance with JIS B 0601(2001).

When the metal layer is formed on the polyaniline layer by electroless plating, the surface roughness Rz_{JIS} measured on the surface of the polyaniline layer prior to being subjected to electroless plating, that is, the surface of the polyaniline layer, on which the metal layer is later formed, is defined as the surface roughness Rz_{JIS} of the surface of the metal layer facing the polyaniline layer.

The thickness of the metal layer is not particularly limited. In one embodiment, the film thickness of the metal layer may be, for example, 0.1 μm or more, 0.3 μm or more, 0.5 μm or more, 0.8 μm or more, 1 μm or more, 5 μm or more, 10 μm or more, 18 μm or more, or 30 μm or more. The thickness of the metal layer may be, for example, 500 μm or less, 300 μm or less, 200 μm or less, 150 μm or less, 100 μm or less, or 50 μm or less.

### [Application]

In one embodiment, the metal layer of the circuit substrate is used for applications to transmit electrical signals. According to one embodiment of the circuit substrate, transmission loss can be prevented regardless of the frequency of the electrical signal.

Further, in one embodiment, the metal layer is used for applications to transmit high-frequency electrical signals having a frequency of 1 GHz or more. The high-frequency electrical signals may have a frequency of 3 GHz or more, 4 GHz or more, 5 GHz or more, 7 GHz or more, 10 GHz or more, 15 GHz or more, 20 GHz or more, 25 GHz or more, 30 GHz or more, 50 GHz or more, 80 GHz or more, 100 GHz or more, or 110 GHz or more, for example. The upper limit of the frequency is not particularly limited, and may be, for example, 200 GHz or less. According to one embodiment of the circuit substrate, transmission loss can be suppressed even when transmitting such high-frequency electrical signals.

The configuration of the circuit substrate is not particularly limited and may be, for example, a printed wiring board (PWB), a printed circuit board (PCB), or a flexible printed circuit (FPC).

### [Method of Manufacturing Circuit Substrate]

The method of manufacturing a circuit substrate according to one embodiment of the invention can be used to manufacture the circuit substrate described above.

In one embodiment, the method of manufacturing circuit substrate includes:

(A) a step of subjecting a surface of the resin base material to one or more treatments selected from the group consisting of an active energy ray irradiation treatment, a corona treatment, and a frame treatment;
(B) a step of forming a polyaniline layer on the surface of the resin base material undergone the treatment;
(C) a step of having an electroless plating catalyst supported on the polyaniline layer; and
(D) a step of applying electroless plating on the polyaniline layer on which the electroless plating catalyst is supported, to form a metal layer.

### [Step (A)]

In the step (A), the surface of the base material is subjected to one or more treatments selected from the group consisting of an active energy ray irradiation treatment, a corona treatment, and a frame treatment.

In this specification, an “active energy ray” has an activity of modifying a surface of the base material, and one capable of increasing adhesiveness between the base material and the polyaniline layer by such modification can be used. The evaluation method of “adhesiveness before plating” described in Example is used as a method of evaluating the increase of adhesiveness. Examples of such an active energy ray include ultraviolet ray, electron beam, and X-ray, and among these, ultraviolet ray is preferred. The ultraviolet ray is not particularly limited, and for example, ultraviolet ray from a light source such a high-pressure mercury lamp or a metal halide lamp can be used.

### [Step (B)]

In the step (B), a polyaniline layer is formed on the surface of the base material undergone one or more treatments selected from the group consisting of an active energy ray irradiation treatment, a corona treatment, and a frame treatment. The method of forming the polyaniline layer is not particularly limited, and for example, application process or the like can be used. The application process is not particularly limited as long as the polyaniline layer can be formed by applying a coating liquid, and various coating methods, printing methods, and the like can be employed, for example, the application process can be selected from the group consisting of bar coating, spin coating, knife coating, blade coating, squeeze coating, reverse roll coating, gravure roll coating, curtain coating, spray coating, die coating, dipping, comma coating, dispenser, pad printing, gravure printing, flexography, and ink jet printing. In one embodiment, when bar coating process is used as an application process, the surface of the polyaniline layer can be more smoothed.

In one embodiment, the coating liquid used for the application process may contain a substituted or unsubstituted polyaniline and a solvent. In this case, a polyaniline layer is formed by drying to remove the solvent.

The solvent is not particularly limited, and examples thereof include e.g., methanol, ethanol, isopropyl alcohol, 2-methoxyethanol, 2-ethoxyethanol, diacetone alcohol, 3-methoxy-1-butanol, 3-methoxy-3-methyl-1-butanol, ethyl carbitol, acetone, methyl ethyl ketone, methyl isobutyl ketone, cyclohexanone, isophorone, solvent naphtha, tetrahydrofuran, diethyl ether, n-butyl acetate, n-butanol, propylene glycol monomethyl ether acetate, γ-butyrolactone, tetralin, 2-butoxy-2-ethoxyethanol, dipropylene glycol monopropyl ether, 1,3-dimethylimidazolidinone, N-methylpyrrolidone, and the like. These may be used alone or in combination of two or more thereof.

Alternatively, instead of use of the solvent, a solvent-free system can be used in which a monomer, an oligomer, or a polymer curable by ultraviolet ray, electron beam or the like is added to adjust the liquid property such as viscosity. The cured product of these monomers, oligomers or polymers may be contained in the polyaniline layer as a binder.

In addition, the coating liquid may contain components described as the components which can be contained in the polyaniline layer.

In one embodiment, the coating liquid (composition) contains a polyaniline complex doped by a dopant described above as the substituted or unsubstituted polyaniline. The concentration of the polyaniline complex in the composition may be, for example, 50% by mass or less, 40% by mass or less, 30% by mass or less, 20% by mass or less, or 15% by mass or less. Such a low concentration of the polyaniline complex in the composition described above, allow the thixotropic property of the composition to be lowered, to increase the smoothness of the polyaniline layer to be coated, and the surface roughness Rz_{JIS} of the surface of the metal layer facing the polyaniline layer to be suitably adjusted to 0.5 μm or less. The concentration of the polyaniline complex in the composition may further be 13% by mass or less, 10% by mass or less, 8% by mass or less, or 5% by mass or less. The lower limit of the concentration of the polyaniline complex in the composition is not particularly limited, and may be, for example, 1% by mass or more.

After forming the polyaniline layer and before forming the metal layer, a degreasing step may be performed. In the degreasing step, the surface of the electroless plating base film is degreased and washed with a surfactant or a solvent such as an alcohol to increase wettability. As the surfactant, an anionic, cationic, or nonionic surfactant may be used as appropriate. When a cationic surfactant is used, for example, the cationic surfactant can be used by diluting to 1 to 3% by mass with ion-exchanged water or the like. Note that the dilution ratio may be appropriately adjusted depending upon the type of the surfactant, the solvent, or the like used for degreasing and washing.

### [Step (C)]

In the step (C), an electroless plating catalyst is supported on the polyaniline layer. The step (C) can be performed after forming the polyaniline layer, preferably after the degreasing step.

Examples of the electroless plating catalyst include, for example, Pd metal (catalyst metal) and the like. In order to support the electroless plating catalyst on the polyaniline layer, the polyaniline layer can be brought into contact with a solution containing an electroless plating catalyst.

When Pd is used as the electroless plating catalyst, the Pd compound solution is contacted with the polyaniline layer. Pd ions are adsorbed to the polyaniline, preferably the polyaniline complex, and reduced to the Pd metal due to their reducing action. The reduced Pd, i.e. Pd in the metal state, exhibits a catalytic action in electroless plating. The amount of Pd deposited per unit area, which includes Pd ions and Pd metals, may be, for example, 1.7 μg/cm² or more, or 2.5 μg/cm² or more.

Examples of the Pd compound include palladium chloride and the like. As a solvent used for the Pd compound solution, for example, hydrochloric acid or the like can be used. Specific examples of the Pd compound solutions include, for example, 0.02% palladium chloride-0.01% aqueous hydrochloric acid (pH3) and the like.

The contact temperature of the polyaniline layer and the Pd compound solution is not particularly limited and may be appropriately set, and is, for example, 20 to 50° C., or 30 to 40° C., and the contact time is not particularly limited and can be appropriately set, and may be, for example, 0.1 to 20 minutes, or 1 to 10 minutes.

### [Step (D)]

In the step (D), a metal layer is formed by subjecting electroless plating on the polyaniline layer on which the electroless plating catalyst is supported. By bringing the polyaniline layer on which the electroless plating catalyst is supported into contact with the electroless plating solution, a metal layer is formed as an electroless plated coat on the polyaniline layer.

The metal species (plating metal) contained in the electroless plating solution is not particularly limited, and for example, one or more metals selected from the group consisting of Cu, Ni, Au, Pd, Ag, Sn, Co, and Pt may be contained. In one embodiment, the electroless plating solution contains Cu. The electroless plating solution may further contain elements such as phosphorus, boron, iron, and the like, in addition to the elements mentioned above.

The contact temperature of the polyaniline layer and the electroless plating solution can be appropriately set in consideration of the type of the plating bath, the desired thickness of the metal layer, and the like, and is, for example, about 20 to 50° C. in the case of a low temperature bath and 50 to 90° C. in the case of a high temperature bath.

In addition, the contact time of the polyaniline layer and the electroless plating solution can be appropriately set in consideration of the type of the plating bath, the desired thickness of the metal layer, and the like, and is, for example, 1 to 120 minutes.

The metal layer may be composed only of the electroless plated coat formed as described above, or may be further provided with the same metal film or a different metal film by electrolytic plating after the electroless plated coat is provided.

### EXAMPLES

### Production Example 1

### [Production of the Polyaniline Complex]

A solution obtained by dissolving 37.8 g of “Aerosol OT” (sodium di-2-ethylhexylsulfosuccinate) (AOT) and 1.47 g of “Sorbon T-20” (manufactured by Toho Chemical Industry Co., Ltd.) as a nonionic emulsifier having a polyoxyethylene sorbitan fatty acid ester structure in 600 mL of toluene was put in a 6 L separable flask placed under a steam of nitrogen, and 22.2 g of aniline was further added to this solution. Thereafter, 1800 mL of 1 M phosphoric acid was added to the solution, and the temperature of the solution having two liquid phases of toluene and water was cooled to 5° C.

When the internal temperature of the solution reached 5° C., the solution was stirred at 390 revolutions per minute. A solution of 65.7 g of ammonium persulfate dissolved in 600 mL of 1 M phosphoric acid was added dropwise over a period of 2 hours using a dropping funnel. The reaction was carried out for 18 hours from the start of the dropwise addition, while the internal temperature of the solution was kept at 5° C. Thereafter, the reaction temperature was increased to 40° C., and the reaction was continued for 1 hour. Thereafter, the reaction solution was allowed to stand, and the toluene phase was separated. To the obtained toluene phase, 1500 mL of toluene was added, washed once with 500 mL of 1 M phosphoric acid and 3 times with 500 mL of ion-exchanged water, and the toluene phase was separated after standing. solution. The concentration of the polyaniline complex in this polyaniline complex toluene solution was 5.7% by mass.

The obtained polyaniline complex toluene solution was dried under reduced pressure in a water bath at 60° C., to dryness to obtain 51.3 g of a polyaniline complex (powder).

The weight average molecular weight of the polyaniline molecule in this polyaniline complex was 72,000 g/mol, and the molecular weight distribution was 2.0.

### Example 1

### Preparation of Coating Liquid 1

27 g of propylene glycol monobutyl ether, 53 g of anone, and 9 g of toluene were mixed to prepare a mixed solvent. 1.2 g of polyester resin (“Vylon GK810” manufactured by TOYOBO CO., LTD.), 6 g of polyester urethane resin (“Vylon UR1350” manufactured by TOYOBO CO., LTD.), and 1 g of a curing agent (“JA-980” manufactured by JUJO CHEMICAL CO., LTD.) were dissolved in the mixed solvent. To the solution, 2.7 g of the polyaniline complex obtained in Production Example 1 was dissolved. A resin modifier (“VD-3” manufactured by SHIKOKU CHEMICALS CORPORATION) was dispersed to the solution to obtain a coating liquid 1. The concentration of the polyaniline complex in the total solid content in the coating liquid 1 was 39%.

### [Production and Evaluation of the Circuit Substrate]

### (Active Energy Ray Irradiation Step)

With the use of an ultraviolet irradiation apparatus (“Conveyor UV irradiation apparatus” manufactured by GS Yuasa Corporation, a light source: metal halide lamp), the surfaces of a base material, SPS resin-molded sheet (XAREC (registered trademark) manufactured by Idemitsu Kosan Co., Ltd., dielectric loss tangent of 0.005 (10 GHz)) was irradiated by ultraviolet ray of the active energy ray, under the condition of 1000 mJ/cm².

### (Forming Polyaniline Layer (Printing and Applicating Step))

On the surface irradiated with ultraviolet ray of the SPS resin film, a coating liquid 1 was applied by using a bar coater (No. 16). The coating film was dried for 30 minutes at 150° C., and cured to obtain a polyaniline layer (electroless plating undercoat film). Here, the applicating amount of the coating liquid 1 was adjusted so that the film thickness of the polyaniline layer measured by the tactile-needle type film thickness meter became 1 μm. The SPS resin molded sheet on which the polyaniline layer was formed, was cut into 50 mm×100 mm to obtain a test piece.

### (Measurement of the Surface Roughness Rz_{JIS})

The surface roughness Rz_{JIS} of the surface of the polyaniline layer of the obtained test piece (the surface of the polyaniline layer opposite the base material) was measured in accordance with JIS B 0601:2001. The measured value is shown in Table 1 as the surface roughness Rz_{JIS} of the metal layer to be formed on the polyaniline layer.

### (Evaluation of Adhesiveness Before Plating)

The obtained test piece (for evaluating adhesiveness) was subjected to an adhesion test in accordance with JIS K5600-5-6 (1999). Evaluation was performed according to the following criteria as defined in JIS K5600-5-6, and Categories 0 and 1 were defined as “◯” (acceptable), and Categories 2 to 5 were defined “×” (rejected). The results are shown in Table 1.
0: The edges of the cuts are perfectly smooth and there is no peeling on any grid.
1: Small peeling of the coating film at the intersection of the cuts. The cross-cut area is clearly not affected by more than 5%.
2: The coating is peeling off along the edges of the cuts and/or at the intersection. The cross-cut area is clearly affected by more than 5% but never more than 15%.
3: The coating film is partially or wholly peeled off along the edges of the cuts, and/or various parts of the square are partially or wholly peeled off. The cross-cut area is clearly affected by more than 15% but not more than 35%.
4: The coating film is partially or wholly peeled off along the edge of the cuts, and/or some squares are partially or wholly peeled off. The cross-cut area is clearly not affected by more than 35%.
5: Any degree of peeling that cannot be classified even in Category 4.

### (Degreasing Step)

The above test piece was immersed in 2.5% by mass aqueous solution of a surfactant (“ACE CLEAN” manufactured by Okuno Chemical Industries Co., Ltd.) for 5 minutes at 55° C. Thereafter, the surface of the test piece was washed with running water and then immersed in 10% by mass aqueous sodium bisulfite solution for 5 minutes at 60° C. Further, the surface of the test piece was washed with running water to do degreasing treatment.

### (Catalyst Supporting Step)

The entire test piece after the degreasing treatment was immersed in 20-fold dilution of a catalytic treatment agent activator (hydrochloric acidic Pd compound solution, manufactured by Okuno Chemical Industries Co., Ltd.) for 5 minutes at 30° C., and a treatment for supporting metal Pd (electroless plating catalyst) on the polyaniline layer was performed.

### (Metal Layer Forming Step)

The test piece after the catalyst supporting treatment was subjected to a plating treatment at 60° C. for 60 minutes using an electroless copper plating solution (Sulcup ELC-SP manufactured by Uyemura & Co., Ltd.) to form an electroless copper plating layer (a metal layer containing copper), and then washed with running water and dried with warm air (80° C.) to obtain a circuit substrate.

(Evaluation of Adhesiveness after Plating)

The obtained circuit substrate was subjected to adhesiveness test in the same manner as in (Evaluation of adhesiveness before plating), and evaluated using the same criteria. Note that this evaluation was performed only for those in which the result of (Evaluation of adhesiveness before plating) was “◯”. The results are shown in Table 1.

### Example 2

The circuit substrate was manufactured and evaluated in the same manner as in Example 1 except that a polyimide film (Kapton EN manufactured by DU PONT-TORAY CO., LTD., dielectric loss tangent: 0.0126 (10 GHz)) was used as the base material instead of the SPS resin film. The results are shown in Table 1.

### Example 3

The circuit substrate was manufactured and evaluated in the same manner as in Example 1 except that a liquid crystal polymer film (dielectric loss tangent: 0.015 or lower (10 GHz)) was used as the base material instead of the SPS resin film. The results are shown in Table 1.

### Comparative Example 1

35 g of 3-methyl-3-methoxybutanol, 5 g of butyl carbitol, and 10 g of petroleum naphtha were mixed to obtain a mixed solvent. To the mixed solvent, 30 g of an urethane resin (“MAU1008” manufactured by Dainichiseika Color & Chemicals Mfg. Co., Ltd.), 6 g of an urethane resin (“ASPU-360” manufactured by DIC Corporation), 0.3 g of an epoxy resin (“HP-4710” manufactured by DIC Corporation), and 0.3 g of a polyvinyl acetal resin (“KS-10” manufactured by Sekisui Jushi Corporation) were dissolved, and 13.3 g of the polyaniline complex obtained in Production Example 1 was dissolved to obtain a coating liquid 2. The concentration of the polyaniline complex in the total solid content in the coating liquid 2 is 50% by mass.

The circuit substrate was manufactured and evaluated in the same manner as in Example 1, except that the coating liquid 2 was used instead of the coating liquid 1 in the formation of the polyaniline layer (printing and applicating step) of Example 1, and the polyaniline layer having a thickness of 6 μm was formed by screen printing. The results are shown in Table 1.

### Comparative Example 2

The circuit substrate was manufactured in the same manner as in Example 1 except that the (Active energy ray irradiation step) of Example 1 was not performed. The adhesiveness before plating was “x.” The polyaniline layer peeled off during the (Metal layer forming step), and the circuit substrate could not be formed.

TABLE 1

| | Exam- | Exam- | Exam- | Comp. | Comp. |
|---|---|---|---|---|---|
| | ple 1 | ple 2 | ple 3 | Ex. 1 | Ex. 2 |
| Base material | SPS | Polyimide | LCP | SPS | SPS |
| Surface roughness | 0.23 | 0.24 | 0.22 | 0.77 | 0.23 |
| Rz_{JIS} of polyaniline layer | | | | | |
| (Surface roughness | | | | | |
| Rz_{JIS} of metal layer) | | | | | |
| [μm] | | | | | |
| Adhesiveness | ○ | ○ | ○ | ○ | × |
| before plating | | | | | |
| Adhesiveness | ○ | ○ | ○ | ○ | − |
| after plating | | | | | |

### Example 4

### (Manufacturing of Copper Clad Stacked Film)

The coating liquid 1 was applied (bar-coated) to one surface of a SPS resin film (thickness: 50 μm, dielectric loss tangent: 0.0004), which was subjected to ultraviolet irradiation treatment on both surfaces, using a bar-coater (No. 8), and dried at 150° C. for 10 minutes. Then, on the other surface of the SPS resin film, the coating liquid 1 was applied (bar coated) using a bar coater (No. 8) and dried at 150° C. for 15 minutes. The film thicknesses of the polyaniline layer after drying (electroless plated undercoat film) thus formed on both surfaces were about 0.8 μm, respectively. The film thickness was measured by the same tactile-needle type film thickness meter as used in Example 1.

The obtained test piece was subjected to the degreasing step, the catalyst supporting step, and the metal layer forming step (electroless plating step) on both sides in the same manner as in Example 1 to form an electroless copper plating layer (a metal layer containing copper) having a thickness of 1 μm, respectively. Next, the film thickness (copper thickness) of the metal layer (copper layer) was increased up to 12 μm by electroplating under the condition of current density of 2 A/dm² using a copper sulfate bath to obtain a double-sided copper clad film.

### (Manufacturing of the Microstrip Line)

A microstrip line and ground (GND) terminals were formed on the resulting double-sided copper clad film according to the procedures described below.

First, a GND terminal was formed on the resulting double-sided copper clad film to conduct copper layers on the front and back of the double-sided copper clad film by drilling and through-hole plating. A total of four GND terminals were formed at each of one end and the other end of the microstrip line (width: 140 μm, length: 100 mm) in the longitudinal direction, and on both sides of the microstrip line in the width direction. Here; although the microstrip line was not yet formed at this stage of forming the GND terminals, the position of the GND terminals are explained with reference to the forming position of the microstrip line. With the above-mentioned through-hole plating, the final copper thickness of each surface of the double-sided copper clad film became 18 μm.

Next, the copper layer on one side (front side) of the double-sided copper clad film was etched to form the microstrip line described above. On the other hand, the copper layer on another side (back side) of the double-sided copper clad film was not etched, the entire surface of the copper layer on another side was a ground (GND). In this way, a substrate for measuring transmission loss was obtained.

The surface roughness Rz_{JIS} of the copper layer (metal layer) on the SPS resin film (base material film) side (corresponding to the polyaniline layer side) was 0.4 μm. The surface roughness Rz_{JIS} is a value measured as the surface roughness Rz_{JIS} of the surface of the polyaniline layer (the surface of the polyaniline layer facing away from the base material) in the same manner as in Example 1.

### (Measurement of Transmission Loss)

The transmission loss was measured from the S parameter of 10 MHz to 110 GHz for the microstrip line of the obtained substrate for measuring transmission loss by using a network analyzer “N5247” (Keysight Technologies). The results are shown in Table 2.

### Comparative Example 3

A commercially available copper foil (JX Nippon Mining & Metals Corporation, copper thickness: 12 μm thick, Rz_{JIS}=4.0 μm) was melted and pressed onto each side of a SPS resin film (thickness: 50 μm, dielectric loss tangent: 0.0004), which was subjected to ultraviolet irradiation treatment on both surfaces, by a vacuum-pressing device at 220° C. to obtain a double-sided copper clad film. The GND terminals were formed by drilling and through-hole plating in the same manner as in Example 4, and the copper foil on one side was etched to form a microstrip line to obtain a substrate for measuring transmission loss. The transmission loss of the obtained substrate for measuring transmission loss was measured in the same manner as in Example 4, and the results are shown in Table 2.

### Comparative Example 4

A commercially available double-sided copper clad flexible substrate (base material: liquid crystal polymer having a thickness of 50 μm, copper thickness: 12 μm, Rz_{JIS}=1.0 μm, dielectric constant at 10 GHz: 2.9, dielectric loss tangent: 0.002) was provided, GND terminals were formed by drilling and through-hole plating, and a microstrip line was formed by etching copper foil on one side of the substrate in the same manner as in Example 4 to obtain a substrate for measuring transmission loss. The transmission loss of the obtained substrate for measuring transmission loss was measured in the same manner as in Example 4. The results are shown in Table 2.

### Comparative Example 5

A commercially available double-sided copper clad flexible substrate (base material: polyimide having a thickness of 50 μm, copper thickness: 12 μm, Rz_{JIS}: 1.0 μm, dielectric constant at 10 GHz: 3.2, dielectric loss tangent: 0.02) was provided, GND terminals were formed by drilling and through-hole plating, and a microstrip line was formed by etching copper foil on one side of the substrate in the same manner as in Example 4 to obtain a substrate for measuring transmission loss. The transmission loss of the obtained substrate for measuring transmission loss was measured in the same manner as in Example 4, and the results are shown in Table 2.

TABLE 2

| | | Exam- | | Comp. | | Comp. | | Comp. | |
|---|---|---|---|---|---|---|---|---|---|
| | | ple 4 | | Ex. 3 | | Ex. 4 | | Ex. 5 | |
| Base material | | SPS | | SPS | | Liquid | | Poly- | |
| | | | | | | crystal | | imide | |
| | | | | | | polymer | | | |
| Dielectric loss | | 0.0004 | | 0.0004 | | 0.002 | | 0.02 | |
| tangent of the | | | | | | | | | |
| base material | | | | | | | | | |
| Surface roughness | | 0.4 | | 4.0 | | 1.0 | | 1.0 | |
| Rz_{JIS} of the metal | | | | | | | | | |
| layer [μm] | | | | | | | | | |
| Trans- | 30 GHz | −4.9 | dB | −6.9 | dB | −5.1 | dB | −8.1 | dB |
| mission | 60 GHz | −9.0 | dB | −12.2 | dB | −11.3 | dB | −17.0 | dB |
| loss | 80 GHz | −13.1 | dB | −17.4 | dB | −16.5 | dB | −24.5 | dB |
| | 100 GHz | −18.6 | dB | −23.9 | dB | −24.0 | dB | −32.8 | dB |

### (Power Attenuation)

The following relationship exists between transmission loss and power attenuation.
−6 dB: Attenuates to about 1/4 as power
−10 dB: Attenuates to about 1/10 as power
−20 dB: Attenuates to about 1/100 as power

It can be seen that the transmission loss of high-frequency wave above millimeter waves can be significantly reduced by the use of the circuit substrate obtained in Example 4.

### INDUSTRIAL APPLICABILITY

The circuit substrate of the invention can be used as a circuit substrate such as an in-vehicle radar or a next-generation mobile phone.

Although only some exemplary embodiments and/or examples of this invention have been described in detail above, those skilled in the art will readily appreciate that many modifications are possible in the exemplary embodiments and/or examples without materially departing from the novel teachings and advantages of this invention. Accordingly, all such modifications are intended to be included within the scope of this invention.

The documents described in the specification and the specification of Japanese application(s) on the basis of which the present application claims Paris convention priority are incorporated herein by reference in its entirety.

1. A circuit substrate comprising, in the following stacked order,
a resin base material having a dielectric loss tangent of 0.015 or lower,
a polyaniline layer comprising a substituted or unsubstituted polyaniline, and
a metal layer,
wherein the metal layer has a surface roughness Rz_{JIS} of 0.5 μm or less at the surface on the side of the polyaniline layer.

2. The circuit substrate according to claim 1, wherein the metal layer has a surface roughness Rz_{JIS} of 0.25 μm or less at the surface on the side of the polyaniline layer.

3. The circuit substrate according to claim 1, wherein the polyaniline layer has a thickness of 5 μm or less.

4. The circuit substrate according to claim 1, wherein the resin base material comprises one or more selected from the group consisting of syndiotactic polystyrene, polyimide, liquid crystal polymer, polytetrafluoroethylene, and polyolefin.

5. The circuit substrate according to claim 1, wherein the resin base material comprises syndiotactic polystyrene.

6. The circuit substrate according to claim 1, wherein the metal layer comprises one or more metals selected from the group consisting of Cu, Ni, Au, Pd, Ag, Sn, Co, and Pt.

7. The circuit substrate according to claim 1, wherein the metal layer comprises Cu.

8. The circuit substrate according to claim 1, wherein the polyaniline layer comprises a polyaniline complex doped by a dopant as the substituted or unsubstituted polyaniline.

9. The circuit substrate according to claim 8, wherein the dopant is an organic acid ion derived from a sulfosuccinic acid derivative represented by the following formula (III): 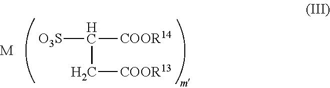
wherein in the formula (III), M is a hydrogen atom, an organic free radical, or an inorganic free radical; m′ is the valence of M; R¹³ and R¹⁴ are independently a hydrocarbon group, or —(R¹⁵O)ᵣ—R¹⁶ group; R¹⁵'s are independently a hydrocarbon group or a silylene group; R¹⁶ is a hydrogen atom, a hydrocarbon group, or a R¹⁷₃Si— group; r is an integer of 1 or more; and R¹⁷'s are independently a hydrocarbon group.

10. The circuit substrate according to claim 8, wherein the dopant is sodium di-2-ethylhexyl sulfosuccinate.

11. The circuit substrate according to claim 1, which is used in applications for transmitting a high-frequency electrical signal having a frequency of 1 GHz or more.

12. A process for manufacturing a circuit substrate according to claim 1, wherein the process for manufacturing a circuit substrate comprises:
a step of subjecting a surface of the resin base material to one or more treatments selected from the group consisting of an active energy ray irradiation treatment, a corona treatment, and a frame treatment;
a step of forming a polyaniline layer on the surface of the resin base material undergone the treatment;
a step of having an electroless plating catalyst supported on the polyaniline layer; and
a step of applying electroless plating on the polyaniline layer on which the electroless plating catalyst is supported, to form a metal layer.

13. The process for manufacturing a circuit substrate according to claim 12, wherein the surface of the resin base material is subjected to an active energy ray irradiation treatment.

14. The process for manufacturing a circuit substrate according to claim 13, wherein the active energy ray is ultraviolet ray.

15. The process for manufacturing a circuit substrate according to claim 14, wherein a light source of the ultraviolet ray is a high-pressure mercury lamp or a metal halide lamp.

16. The process for manufacturing a circuit substrate according to claim 12, wherein the polyaniline layer is formed by coating method using a composition comprising a substituted or unsubstituted polyaniline.

17. The process for manufacturing a circuit substrate according to claim 16, wherein the composition comprises a polyaniline complex doped by a dopant as the substituted or unsubstituted polyaniline.

18. The process for manufacturing a circuit substrate according to claim 17, wherein the composition comprises the polyaniline complex of a concentration of 15% by mass or less.

19. The process for manufacturing a circuit substrate according to claim 12, wherein the electroless plating catalyst is Pd.
